(19) United States
(12) Patent Application Publication
(10) Pub. No.: US 2009/0162535 A1
(43) Pub. Date: Jun. 25, 2009

(54) METHOD OF FORMING A PHOSPHOR OR SCINTILLATOR MATERIAL AND VAPOR DEPOSITION APPARATUS USED THEREFOR

(76) Inventors: Jean-Pierre Tahon, Langdorp (BE); Paul Leblans, Kontich (BE)

Correspondence Address: NEXSEN PRUET, LLC, P.O. BOX 10648, GREENVILLE, SC, 29603, US

(21) Appl. No.: 11/962,515

(22) Filed: Dec. 21, 2007

(51) Int. Cl. B05D 5/06; C23C 16/00

(52) U.S. Cl. 427/69; 118/726

(57) ABSTRACT

In a method of preparing a storage phosphor or a scintillator layer on a support by vapor depositing from a crucible unit in a vapor deposition apparatus, while heating as phosphor or scintillator precursor raw materials a matrix component and an activator component or a precursor component thereof, said crucible unit comprises a bottom and surrounding side walls as a container for the said phosphor or scintillator precursor raw materials present in said crucible, said crucible is provided with an internal lid with perforations (5) and said crucible unit further comprises a chimney as part of the said crucible unit and a slit allowing molten, liquefied phosphor or scintillator precursor raw materials to escape in vaporized form under reduced pressure from said crucible unit in order to become deposited as a phosphor or scintillator layer onto said support; and at least one heating means (1) in the chimney (2) is positioned under a heat shield with a slit (3) and a slot outlet (3′), covering thereby said crucible unit and making part of said chimney (2), so that said heating means (1) cannot be observed when looking into the vaporization unit through said slot outlet (3′) from any point in the plane of the said support present as a vapor deposition target in the said vapor deposition apparatus and, while vaporizing said phosphor or scintillator precursor raw materials, a vapor cloud escapes from said slot outlet (3′) in the direction of the said support so that the ratio of the longest radius of the said vapor cloud versus the radius perpendicular thereto, when projected onto the phosphor or scintillator plate or panel from whatever an intersection through the said vapor cloud between slot outlet (3′) and support is at least 1.3, said intersection being taken parallel with the said support.

### FIELD OF THE INVENTION

The present invention relates to a method of preparing a storage phosphor or scintillator plate by a vapor deposition process. More particularly the invention is related to vapor deposition from a dedicated crucible unit in a vapor deposition apparatus in order to optimize the steering of the vapor cloud while performing vapor deposition onto a support, mounted in the said apparatus.

### BACKGROUND OF THE INVENTION

In a vapor deposition process, performed in a vapor deposition apparatus, following configurations in said apparatus are known from the prior art. The contents of all of the references cited is incorporated herein by reference.

As described in WO 90/12485 an apparatus for use in a physical vapor deposition process comprises at least two evaporators with means in order to maintain each evaporator at an independent temperature, a temperature controlled collector, a vessel which embraces or communicates with the evaporators said vessel defining therewithin a vapor mixing chamber having a discharge opening facing the deposition support, and means in order to maintain the vessel walls in the part thereof, delimiting the vapor mixing chamber at a temperature at least as high as the hotter or hottest evaporator thereby in order to enhance mixing of the respective vapor streams, whilst suppressing condensation of vapor on the chamber walls: evaporators are located at differing levels versus the position of the deposition support, so that the evaporator containing the less volatile component is at a level between the other evaporator with the most volatile component and the deposition support, i.e., more close to the chimney walls and chimney slot outlet (3′).

Another configuration is described in WO 92/07103 and U.S. Pat. No. 5,348,703 as a centrally positioned crucible with the less volatile component, wherein said less volatile component is electron beam radiated in order to become vaporized; wherein said centrally positioned crucible is surrounded by crucibles filled with the more volatile component and heated by means of radiant heaters and wherein vapor streams of the more volatile component are led through nozzles into the vapor stream of the electron beam vaporized less volatile component in order to become deposited together onto a support.

In the more recently issued U.S. Pat. No. 6,875,990 a method for preparing a radiation image storage panel has been described, said method comprising the preparation of on a substrate of a phosphor layer of a stimulable CsBr:Eu phosphor, said method comprising vaporizing one or more vaporization sources comprising a mother component and one or more vaporization sources comprising a europium element such that the vaporization of the mother component sources is controlled independent on the vaporization of the europium element sources, in order to form a storage phosphor layer on a substrate providing thereby a photostimulable phosphor screen or panel, suitable for use in computed radiography.

A vapor deposition apparatus, developed in particular for on-line deposition of such a phosphor or, alternatively, a scintillator material as described in US-A 2005/0000448, comprises a crucible containing a mixture of raw materials, a chimney having at least one outlet in communication with the said crucible and a linear slot outlet, one or more linear heating elements, contained within said chimney, an oven surrounding said crucible, wherein said oven contains heating elements, shielding elements and cooling elements.

Even more recently in US-Application 2005/0160979 a film deposition system for depositing a polycrystalline film on a large area substrate has been disclosed. The system includes a chamber formed of a set of walls, the set of walls defining at least three temperature zones within the chamber. Each of the walls is thermally insulated from the other walls forming the chamber. The system further includes a vacuum source, a set of heat sources, and a plurality of temperature detectors for detecting the temperature of the walls in the set of walls. Temperature control modules monitor and control the temperature in each of the temperature zones. The temperature control modules maintain predetermined temperatures in the walls so that the total mass of film-forming material lost through parasitic losses is less than the film mass deposited on the large area substrate. A method for depositing a polycrystalline film is also described. In yet other embodiments of the method, the step of forming includes forming a first, a second and a third temperature zone where the temperatures of the walls are maintained at predetermined temperatures T1, T2, and T3 respectively, the second temperature zone being the zone wherein the rate of condensation of the vapor of the film-forming material is greater than the rate of the evaporation of the material; and the step of providing and positioning further includes the steps of:

positioning the film-forming material in the first temperature zone where its temperature is controlled at the first predetermined temperature T1 so that a phase change may occur and the material may be evaporated;

positioning the substrate in the second temperature zone where its temperature is controlled at the second predetermined temperature T2, T2 being the temperature wherein the rate of condensation exceeds the rate of evaporation of the film-forming material, and wherein

the third temperature zone is situated between the substrate and the film-forming material wherein the third predetermined temperature T3 is controlled to allow the evaporated film-forming material to remain substantially as a vapor as it moves through the chamber toward the substrate for deposition thereon substantially without parasitic deposition in other parts of the chamber. The relationship between T1, T2 and T3 can be such that either T1≧T3>T2, or T1>T2 and T1≦T3>T2.

In US-Application 2004/0219289 application of the method to coat a surface as large as possible in a way to get a homogeneous deposit of phosphor or scintillator material over quite a large screen, sheet, plate or panel surface area has become available. Said method allows quite a lot of configurations in the vapor deposition coating apparatus as set forth therein. Moreover, by making use of a moving flexible substrate supplied in roller form, huge areas deposited with a phosphor layer, become available. Out of these layers the right formats as desired can be cut and laminated against a rigid substrate.

In U.S. Pat. No. 7,070,658 further information has been given with respect to particular parts in the vapor deposition unit, in order to reach the object of further improving homogeneity of vapor deposition, more in particular with respect to the heating systems. Measures in order to maintain the temperature within the crucibles at a level so that condensation of scintillator or phosphor material onto the walls of the chimney is avoided, comprise presence of a heat shield with a slit in order to let the vapors pass. So in the Examples a crucible in form of an elongated boat having a length of 1 m and a width of 4 cm composed of “tantalum” with a thickness of 0.5 mm has been demonstrated with 3 integrated parts: a crucible container, an internally heated chimney and a controllable outlet. The chimney therein is provided with 3 linear radiation heaters with a diameter of 11 mm, emitting moreover, besides infrared radiation, radiation of shorter wavelengths. Preferably said radiation heaters are quartz halogen heaters, present in order to heat the chimney and in order to overcome condensation of vaporized materials. Moreover the chimney heaters have been positioned in a baffled way in order to overcome spatter of molten or vaporized material onto the substrate into an uncontrolled and unlimited way. A lip opening of 5 mm as controllable outlet has been used. A heat shield with slit opening is further shielding heat in order to avoid escape of heat and loss of energy, required to provoke vapor escape and deposit onto the continuously moving substrate support in a controlled and uniform way. Under vacuum pressure (a pressure of 2×10 Pa equivalent with 2×10 mbar) maintained by a continuous inlet of an inert gas like argon or nitrogen into the vacuum chamber (1), not excluding use of dry air, and at a sufficiently high temperature of the vapor source (760° C.) and the chimney, the obtained vapor has been directed towards the moving sheet support and has been deposited thereupon successively while said support has been moving along the vapor stream. Said temperature of the vapor source has been measured by means of thermocouples present outside and pressed under the bottom of said crucible and tantalum protected thermo-couples present in the crucible and in the chimney.

Apart from some particular crucible configurations with a convection member and an indication about a substrate temperature of about 120° C., preferably at least 160° C. for a substrate in a continuous vaporization apparatus, wherein a substrate is radiation heated up to such a substrate temperature, no indication can be found about crucible temperatures in US-A 2005/0103273.

So in US-Application 2005/0186329 no specifically detailed information has further been given with respect to temperatures in the crucibles either: apart for providing a method for producing a binderless phosphor screen or panel by the steps of depositing a CsX:Eu phosphor on a substrate, within a temperature T from Tₘₑₗₜ−100° C. to Tₘₑₗₜ+100° C., wherein melting temperature Tmelt represents the melting temperature of the desired phosphor, no indication or detail has been given about temperatures or desired temperature changes within the crucibles. In this reference an improvement for resistance to moisture of the produced CsBr:Eu screens or panels has been given by making use of selected stable CsₓEu_{y}X′_{x+αy} complexes as starting components for performing the vapor deposition process.

In US-Application 2007/0098880 a method of preparing a storage phosphor layer on a support by vapor deposition makes use of a crucible unit by heating as phosphor precursor raw materials a matrix component and an activator component or a precursor component thereof, wherein said crucible unit comprises at least a bottom and surrounding side walls as a crucible for phosphor precursor raw materials present in said crucible in liquid form, wherein said crucible unit further comprises at least a chimney as part of the crucible unit and a slit allowing phosphor precursor raw materials to escape in vaporized form from said crucible unit in order to deposit it as a phosphor layer onto said support, the step of heating said precursor raw materials in the crucible in liquid form proceeds up to a temperature T1 and the step of heating said precursor raw materials in vaporized form in said chimney, proceeds up to a temperature T2, and wherein a positive difference in temperature [T2−T1] is maintained.

In order to avoid loss of raw phosphor or scintillator material, spattering or bumping from the crucible onto the support or the vapor deposition apparatus walls, the vapor deposition apparatus advantageously comprises as a vaporization assembly a container in form of a boat or crucible and a support for vapor depositing phosphor or scintillator material thereupon from raw materials present in said container, wherein said boat or crucible internally comprises an assembly of two perforated covers or lids, one of which is an outer lid (also called first lid) more close to the said support and the other cover is an inner lid (also called second lid) more close to the bottom of the said crucible; and wherein perforations present in said outer lid represent a total surface exceeding the total surface of perforations present in said inner lid more close to the bottom of the said crucible and wherein in said vapor deposition apparatus the said raw materials or the bottom of the said crucible cannot be directly seen through said perforations from any point of said support; thereby providing the manufacturing of a radiation image storage phosphor layer on a support or substrate, by a vapor depositing step of raw materials of an alkali metal halide salt and a lanthanide dopant salt or a combination thereof in order to ensure vapor deposition of a binderless needle-shaped storage phosphor layer in the said vapor deposition apparatus, so that a ratio between the total surface of perforations in said inner lid more close to the bottom of crucible and the total surface of perforations in said outer lid more close to the support is not more than 1.0, as has been disclosed in U.S. Ser. No. 11/871,272.

None of these references however specifically relates to particularly suitable crucible configurations that moreover provide means to further improve the steering of the vapor cloud escaping from the crucible unit in the vapor deposition process, wherein direct heating of the support or substrate, whereupon the phosphor layer should be deposited, should be avoided. Improving the said steering of the vapor cloud would moreover be desirable from a point of view of the yield of the vapor deposition process, as up to now losses of raw material, not deposited onto the said support or substrate in an amount in the range of up to even 50%, are commonly attained. Such high amounts of raw material, deposited e.g. at the walls of the vapor deposition apparatus, moreover require recovering of expensive raw materials at a high cost.

### SUMMARY OF THE INVENTION

Therefore it is an object of the present invention to improve the deposition yield of raw materials onto the support or substrate of a storage phosphor or scintillator.

The above-mentioned advantageous effects have been realized by a method having the specific features as set out in claim 1.

Specific features for preferred embodiments of the invention are set out in the dependent claims.

Further advantages and embodiments of the present invention will become apparent from the following description and drawings.

### BRIEF DESCRIPTION OF THE DRAWINGS

FIG. 1 shows a chimney heater element (1), an internally heated chimney (2), a heat shield with a slit (or an array of slits in one dimension) (3), a slot outlet (3′) and a crucible, tray or boat (4), an inner lid with perforations (5), isolation means (6) between crucible and chimney, and a “saving” or “reduction” part (7), in order to make the crucible and the chimney fit to each other,and wherein one lamp is present as (additional) chimney heater element (1). Said isolation means (6) in form of a layer or ring between chimney and crucible, together with the position of the chimney heater element (1) in form of a lamp, shielded from the support above the slot outlet (3′) by said heat shield (3) is of utmost importance in order to reach the objects of the present invention.

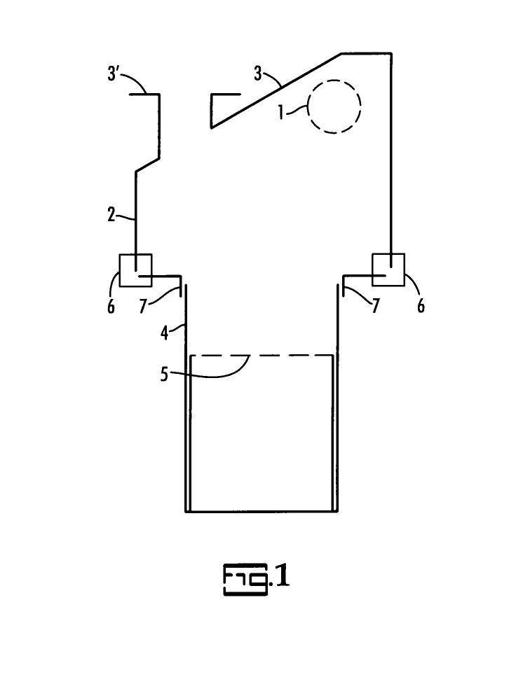

### DETAILED DESCRIPTION OF THE INVENTION

It is known that an expansion of vapor when escaping over a narrow slit provokes that vapor is cooled. As a consequence there is a danger that condensation onto the narrow slit occurs and that spatter and inhomogeneous deposition leads to production of unevenness, spots onto the phosphor or scintillator plate and less sensitive, irreproducible and unstable plates.

A solution has been found now by applying, according to the present invention, a method of preparing a storage phosphor or a scintillator layer on a support by vapor depositing from a crucible unit in a vapor deposition apparatus, while heating as phosphor or scintillator precursor raw materials a matrix component and an activator component or a precursor component thereof, said crucible unit comprising a bottom and surrounding side walls as a container for the said phosphor or scintillator precursor raw materials present in said crucible, said crucible being provided with an internal lid with perforations (5) and said crucible unit further comprising a chimney as part of the said crucible unit and a slit allowing molten, liquefied phosphor or scintillator precursor raw materials to escape in vaporized form under reduced pressure from said crucible unit in order to become deposited as a phosphor or scintillator layer onto said support; wherein at least one heating means (1) in the chimney (2) is positioned under a heat shield with a slit (3) and a slot outlet (3′), covering thereby said crucible unit and making part of said chimney (2), so that said heating means (1) cannot be observed when looking into the vaporization unit through said slot outlet (3′) from any point in the plane of the said support present as a vapor deposition target in the said vapor deposition apparatus and wherein, while vaporizing said phosphor or scintillator precursor raw materials, a vapor cloud escapes from said slot outlet (3′) in the direction of the said support so that the ratio of the longest radius of the said vapor cloud versus the radius perpendicular thereto, when projected onto the phosphor or scintillator plate or panel from whatever an intersection through the said vapor cloud between slot outlet (3′) and support is at least 1.3, said intersection being taken parallel with the said support.

By application of the method according to the present invention direct heating of the said support is avoided as an additional heating means, as e.g. a lamp, is no longer used as a baffle, normally used in order to avoid spatter onto the support as described in the prior art, but wherein a heat shield with a slit covers the vaporization unit and wherein the heating means (as e.g. a lamp) cannot be seen when looking into the vaporization unit through the slot outlet from any point into the vapor deposition apparatus, outside the crucible with chimney as crucible unit.

In a further embodiment according to the present invention, an isolation means (6) is present between said chimney (2) and said crucible (4). The said isolation means (6) is, in one embodiment according to the present invention, present in form of an isolating ring or layer. More particularly said isolating ring or layer comprises as an isolating material an oxide selected from the group consisting of Al₂O₃, SiO₂, quartz, glass, ceramics and a combination thereof.

In a particular embodiment according to the method of the present invention the step of heating said precursor raw materials in the crucible in liquid form proceeds up to a temperature T1 and the step of heating said precursor raw materials in vaporized form in said chimney (2) proceeds by means of said at least one heating means (1) in the chimney (2) up to a temperature T2, wherein a positive difference in temperature [T2−T1] is maintained.

According to the method of the present invention said temperatures T1 and T2 are attained by radiation heating, inductive heating, resistive heating or a combination thereof. Said heating methods applied while pre-heating before starting vaporization or while performing vaporization thus proceed by means of resistive heating, inductive heating, radiation heating or a combination thereof, i.e. by lamps as e.g. quartz lamps or infrared lamps, preference being given to quartz halogen lamps as e.g. for the at least one heating means (1) in the chimney (2).

With respect to further additional heaters as e.g. for the substrate or support, mounted in the vapor deposition apparatus, resistive heaters as well as radiation heaters may be applied. Resistive heaters are defined herein as providing invisible infrared radiation, i.e. radiation in the longer wavelength range above 700 nm, whereas radiation heaters in form of lamps, as e.g. for the at least one heating means (1) in the chimney (2) are emitting, besides infrared radiation in the longer wavelength range above 700 nm, also visible radiation in the spectral wavelength range below 700 nm.

In the method according to the present invention, said temperatures T1 and T2, mentioned hereinbefore are advantageously attained by radiation heating, resistive heating or a combination of radiation heating and resistive heating. In a particular embodiment said temperatures T1 and T2 are attained by radiation heaters emitting radiation having wavelengths below 700 nm besides infrared radiation, wherein quartz halogen lamps are recommended, besides (electrical) resistive heating. Whereas the crucible container is normally heated by resistive heating, the chimney temperature is advantageously enhanced by the said radiation heaters, without however being limited thereto.

According to the present invention, in a further embodiment, a “saving” or “reduction” part (7) is provided between crucible (4) and chimney (2) in order to make the said crucible (4) and the said chimney (2) fit to each other.

In order to avoid spatter, the inner lid with small perforations (5) forms a first barrier, and the position of the said “saving” or “reduction” part (7) versus the slot outlet (3′) is moreover forming an additional barrier against spatter of material from the liquefied raw material surface of the phosphor or scintillator plate in a configuration in the vapor depositing apparatus wherein not any axis perpendicular to the said inner lid (5) of the crucible (4) and not any axis parallel to the said axis and passing through the “saving” or “reduction” part (7) together simultaneously pass through the said slot outlet (3′).

When dimensions of the crucible, i.e. width and length, are not compatible with the dimensions of the chimney, said “reduction” part, which is positioned in contact with isolation means (6), thus overcomes dimensional incompatibility, so that a perfect fitting is provided between crucible (4) and chimney (2) through isolation means (6).

Besides its function as “saving” or “reduction” part, fitting the crucible to the chimney as an “adaptor”, said “saving” or “reduction” part thus helps avoiding direct spatter perpendicular to and from the surface of the molten raw materials in the crucible through the slot outlet (3′) onto the panel substrate or support.

In one embodiment of the method according to the present invention CsX is a matrix component and EuX₂, EuX₃, EuOX or a mixture thereof are activator components, X representing Cl, Br, I or a combination thereof.

In another embodiment of the method according to the present invention CsₓEu_{y}X′_{(x+αy)} is an activator precursor material, wherein x, y and α are integers, wherein x/y is more than 0.25 and wherein α is at least 2 and wherein X′ represents F, Cl, Br, I or a combination thereof.

In still another embodiment of the method according to the present invention CsX′ is a matrix component and T1X′ or T1X′₃ or a mixture thereof are activator components, X′ representing F, Cl, Br, I or a combination thereof.

According to the method of the present invention said storage phosphor is CsBr:Eu, whereas in case of preparing a scintillator material, said scintillator is CsI:T1.

In one embodiment of the method according to the present invention, said vapor deposition proceeds in a batch process.

In another embodiment of the method according to the present invention, said vapor deposition proceeds in a continuous process.

The vapor deposition apparatus according to the present invention thus advantageously comprises a crucible unit consisting of a crucible (4) and a chimney (2), wherein said crucible is provided with an internal lid with perforations (5) and wherein said chimney (2) is covered with a heat shield with a slit (3) and a slot outlet (3′), wherein said chimney (2) comprises at least one chimney heater element (1) positioned asymmetrically versus an axis perpendicular to the center of the said internal lid with perforations (5), in that said chimney heater element(s) is(are) not observed from any point outside said slot outlet (3′).

In one particular embodiment the vapor deposition apparatus according to the present invention is provided with isolation means (6), present between said crucible (4) and said chimney (2).

In another particular embodiment the vapor deposition apparatus according to the present invention is provided with a “saving” or “reduction” part (7), present as a fitting means between said crucible (4) and said chimney (2).

Most advantageously, in favor of avoiding spatter, the vapor deposition apparatus according to the present invention is configured so that not any axis perpendicular to the said inner lid (5) of the crucible (4) and not any axis parallel to the said axis and passing through the “saving” or “reduction” part (7) together pass through the said slot outlet (3′).

The problems solved by the present invention, although being more in favor of smaller vaporization units, is also advantageously applied to a vapor depositing apparatus having a larger volume, such as an apparatus for continuous on-line vaporization, wherein a substrate, attached to one or more rollers is continuously moving along the slit opening of the crucible unit as in US-A's 2004/0219289 and 2004/0224084.

As a solution for the problem of heating of the panel support or substrate in a small vapor depositing apparatus, a cooling unit may be provided, mounted in the vicinity of the crucible unit, outside the crucible, so that the substrate or support temperature is continuously controlled, and, more preferably, steered along a back-coupling mechanism. Nevertheless, steering of the vaporization cloud as such, remains directed by the configuration of the vaporization unit consisting of the crucible and the chimney as set forth hereinbefore, resulting in an advantageous effect of enhancing the yield of the vaporization process, i.e. an increased amount or percentage of deposited phosphor or scintillator material versus the amount of raw materials, initially present in the crucible.

As an advantageous result of vaporization into a vapor deposition apparatus according to the present invention the vaporization cloud escaping from the vaporization unit in the said apparatus is “asymmetric”, i.e., deposition onto the phosphor or scintillator support or substrate of the phosphor or scintillator layer does not proceed in form of a circular deposit, but in form of a deformed circle, i.e. about in form of an ellipse, so that the ratio of the longest radius of the vapor cloud versus the radius perpendicular thereupon, when projected onto the phosphor or scintillator plate or panel from whatever an intersection through the said vapor cloud between slot outlet (3′) and support, said intersection being parallel with the said support as projected onto the phosphor or scintillator plate or panel from whatever a height between said intersection and said support, is at least 1.3.

As an advantageous and unexpected effect of the present invention it has moreover been found that for the same coating amount of phosphor or scintillator in a vaporization process, modified according to the present invention, an enhanced phosphor or scintillator speed is measured for a process, wherein both the more and the less volatile raw material components or precursors are evaporated from one and the same crucible unit having a configuration as disclosed hereinbefore.

The vapor deposition apparatus used for performing the method according to the present invention thus has, in a preferred embodiment, at least one chimney heating element (chimney heater(s)) (1) mounted versus said slot outlet (3′), and positioned so that there is no direct path for vaporized particles from said raw materials to escape through said slot outlet (3′) as an “asymmetric” vapor cloud. In such an arrangement presence of an inner lid or cover, provided with small perforations (5) is more particularly required in order to avoid spattering, wherein the inner lid or cover thus acts as a baffle. A perforated refractory plate as an inner lid (5), e.g. a tantalum plate, is thus mounted internally in the crucible under the chimney heater(s) (1), present in the internally heated chimney (2). Said crucible and said perforated refractory plate is further mounted between an electrode pair, in order to provide further homogeneous heating over the whole heat-conducting assembly, in favor of homogeneous deposition of phosphor or scintillator material. In the vapor deposition apparatus according to the present invention said (controllable) slot outlet (3′) is a rectangular slot outlet. The slot outlet (3′) should not be too high, if compared with the height of the height of the chimney (2), i.e. preferably not more than 50% thereof.

In a particular embodiment in the vapor deposition apparatus suitable for performing the method according to the present invention, said chimney heating element(s) (1) are movable in an upward or downward position.

A substrate or support material whereupon the scintillator or phosphor or scintillator material is deposited in the vapor depositing apparatus used in the method according to the present invention, is composed of glass, a ceramic material, a polymeric material, a metal or a combination thereof. More preferably a material selected from the group consisting of glass, polyethylene therephthalate, polyethylene naphthalate, polycarbonate, polyimide, carbon fibre-reinforced plastic sheets, aluminum, Pyrex®, polymethylacrylate, polymethylmethacrylate, sapphire, zinc selenide, Zerodur®, a ceramic layer and a metal or an alloy selected from the group of aluminum, steel, brass, titanium and copper is applied therefor. It should even not be limited thereto as in principle, any metal or synthetic material resisting irreversible deformation, e.g. as by melting, after addition of energy to the extent as commonly applied in the coating process of the present invention, is suitable for use. Particularly preferred as flexible substrate in method of the present invention is aluminum as a very good heat conducting material allowing a perfect homogeneous temperature over the whole substrate. As particularly useful aluminum substrates, without however being limited thereto, brightened anodized aluminum, anodized aluminum with an aluminum mirror and an oxide package and, optionally, a parylene layer; and anodized aluminum with a silver mirror and an oxide package and, optionally, a parylene layer; available from ALANOD, Germany, are recommended. So as a preferred flexible substrate support an anodized aluminum support layer, covered with a protective foil, is recommended. Such an anodized aluminum support layer may have a thickness in the range of from 50 μm to 500 μm, and more preferably in the range from 200 μm to 300 μm. Such an anodized aluminum substrate has shown to be particularly favorable indeed with respect to adhesion characteristics with respect to vapor deposited phosphors or scintillators and even bending of that flexible aluminum support coated with a scintillator layer having a thickness of 500 μm up to 1000 μm, does not cause “cracks” or delamination of scintillator or phosphor “flakes”. No problems have indeed been encountered with respect to occurrence of undesirable cracks when prepared in the vapor deposition apparatus of the present invention.

While vapor deposition proceeds the temperature of the said flexible substrate is maintained in the range from 150° C. to 300° C., more preferably in the range from 150° C. to 250° C. and still more preferably in the range from 180° C. to 220° C., envisaging a target temperature of about 200° C., by means of regulable radiation heaters. An addressable cooling unit may be installed along the support. More particularly, in favor of a homogeneous coating profile on the roller substrate in case of a continuous vapor deposition process, use is made of halogen quartz lamps providing a better heat absorption by aluminum, wherein said halogen quartz lamps are arranged parallel versus the rotating support. It is advantageous to arrange said individual quartz lamps in a horizontally arranged array consisting of two rows, each of which form overlapping lamp positions, not covered by the neighboring array. Based on those measurements and interpolated calculations, the heating quartz lamps are steered via a back-coupling mechanism: an individual temperature profile steering the temperature of the continuously passing substrate support by a heating/non-heating back-coupling mechanism thereby homogenizes the coating thickness profile in the width direction of the web support to be coated. A reflecting, e.g. parabolic, screen as e.g. a tantalum screen, may advantageously be present behind each lamp of both lamp arrays. As it is important to keep the total heat within the vapor depositing system in order to provide high enough a constant substrate temperature, and as heat losses more probably appear in the vicinity of the support borders, i.e. far from the center of the roller supported support, supplementary quartz lamps are installed in that vicinity in order to compensate for the said heat losses.

Therefore it is recommended to provide a double-faced crucible unit in order to get an isolated crucible and chimney, wherein loss of energy is minimized. Apart from those measures related with homogeneity of thickness of deposited layers, steered variations of the slit opening over the length (in the width direction) of the crucible unit may additionally be useful. Over the whole length of the slit opening titanium blocks are advantageously arranged therefor, wherein addition of energy by resistive heating for each block apart allows expansion of said block in order to make decrease the slit opening by reversibly pressing at particularly required sites. Means in order to control layer thickness and layer thickness profiles of deposited material are advantageously installed to steer the said thickness and in order to control and stop the deposition process when the desired thickness is attained. So in the vapor deposition zone a thickness measuring system, based on capacitance measurements, is installed, thereby determining thickness while vapor depositing said scintillator or phosphor layer. In another embodiment use may be made of a radioactive source, as e.g. a gamma-ray source, providing thickness measurements, based on radiation absorption measurements in that case.

It is evident that the composition of the raw material in the container(s) (crucible(s)) of the vapor depositing apparatus used in the method according to the present invention is chosen in order to provide an end composition or coating composition as desired, wherein said composition is determined by the ratios of raw materials present. Ratios of raw materials are chosen in order to provide the desired chemical phosphor or scintillator composition after deposition of the vaporized raw materials. It is desirable to mix the raw materials in order to get a homogeneous raw mix in the crucible(s) in form of solid powders, grains or granules, or as pastilles having a composition corresponding with the desired ratios of raw materials in order to provide the desired phosphor or scintillator coated onto the moving substrate material. A milling procedure, whether performed before, outside or inside the vapor deposition apparatus, may be favorable in order to provide a high degree of homogeneity before vaporization and is therefore recommended. In case of milling inside the vapor depositing apparatus, said milling step may be performed inside or outside the crucible unit or units. Differing components may also be vaporized from different crucibles, arranged in series or in parallel or in a combined arrangement as already suggested hereinbefore, provided that a homogeneous vapor cloud is presented to the flexible substrate via the vapor stream or flow, deposited by condensation onto said substrate. In another embodiment, if providing a more homogeneous coating profile, crucibles in form of boats may be arranged in parallel on one axis or more axes, perpendicular to the moving direction of the support, provided that overlapping evaporation clouds again are providing a vapor stream that becomes deposited onto the support in a phosphor or scintillator layer having a homogeneous thickness, composition and coated amount of said phosphor or scintillator. Presence of more than one crucible may be in favor of ability to supply greater amounts of phosphor or scintillator material to be deposited per time unit, the more when the flexible substrate should pass the vapor flow at a rate, high enough in order to avoid too high temperature increase of the substrate. The velocity or rate at which the substrate passes the container(s) should indeed not be too slow in view of undesired local heating of the substrate support, making deposition impossible, unless sufficient cooling means are present in favor of condensation. The supporting or supported substrate should therefore preferably have a temperature maintained between 120° C. and 300° C., preferably between 150° C. and 250° C. in order to obtain deposited phosphor or scintillator layers having the desired optimized properties.

It is clear that energy should be supplied to one or more container(s), also known as crucible(s), tray(s) or boat(s), in order to provoke a vapor flow (or stream) of the raw materials present therein, which become vaporized in the sealed vacuum zone: energy is submitted thereto by thermal, electric, or electromagnetic energy sources. As an example of an electromagnetic energy source a diode, a cathode arc, a laser beam, an electron beam, an ion beam, magnetron radiation or radio frequencies may be used, whether or not pulsed, without however being limited thereto. Electric energy is commonly provided by resistive heating, making use of resistance coils wound around the container(s) or crucible(s) in a configuration in order to get conversion into thermal energy, thereby providing heat transfer to the containers or crucibles filled with the raw materials that should be evaporated. Energy supply to an extent in order to heat the container(s) or crucible(s) up to a temperature in the range from 550°-900° C. is highly desired. At those temperatures, it is clear that containers should resist corrosion, so that refractory containers are preferred. Preferred container or crucible materials are tungsten, tantalum, molybdenum and other suitable refractory metals. Energy supply as set forth heats the mixture of raw materials in the crucible to a temperature above 450° C., preferably above 550° C., and even more preferably in the range of 550° C. up to 900° C., e.g. at about 700° C.

From the description above it is clear that, in order to obtain a homogeneous coating profile as envisaged, a homogeneous cloud can only be realized when homogeneity is provided in the bulk of the liquefied raw material, i.e., after some critical time during which a transition from a mixed solid-liquid phase to a liquid phase appears. As a consequence, a homogeneous distribution of energy supplied over the container is a stringent demand. In a preferred embodiment, in favor of homogeneity, the crucible is in form of a single elongated “boat” with a largest dimension corresponding with the width of the flexible support moving over the said crucible so that at each point of its surface area the momentarily velocity magnitude is constant. If required during or after the deposition process oxygen may be introduced into the vacuum deposition chamber via a gas inlet, in form of oxygen gas. Alternatively, dry air may pass the gas inlet. More particularly an annealing step, performed between two deposition steps or at the end of the phosphor or scintillator deposition may be beneficial. An important factor with respect to the coating profile obtainable on the substrate support in the vapor depositing apparatus of the present invention, is the distance between container(s) and moving substrate as the said distance determines the profile of the vapor cloud at the position of the flexible substrate. Average values of shortest distances between crucible(s) and substrate are preferably in the range of from 5 to 10 cm in the continuous process in a large volume vapor deposition apparatus, and said average distances may even be from 10 to 20 cm, more preferably about 15 cm in the batch process, when performed in a smaller volume deposition apparatus. Too large distances would lead to increased loss of material and decreased yield of the process, whereas too small distances would lead to too high a temperature of the substrate, more particularly in the case of a smaller vapor deposition chambers in a vapor deposition apparatus, used in a batch process.

In the vapor depositing apparatus used for performing the method according to the present invention, vapor deposition of said phosphor or scintillator compositions is initiated by a vapor flow of raw materials from one or more crucible(s), wherein said vapor flow is generated by adding energy to said raw materials and said container(s), by thermal, electric, or electromagnetic energy or a combination thereof. So vapor depositing said phosphor or scintillator compositions advantageously proceeds by physical vapor deposition, by chemical vapor deposition or a by combination of physical and chemical vapor deposition.

At the moment of deposition, a preferred stimulable phosphor or scintillator layer, prepared in the vapor depositing apparatus used for performing the method according to the present invention, is a binderless layer. This can be well understood, as at those high temperatures, presence of additional binders besides phosphors or scintillators raw materials in the container(s) would not be practical. It is however not excluded to make use of polymers or dyes, showing ability to become vaporized, e.g. by sublimation, in order to serve as binder material or coloring material, present in a layer e.g. between substrate and phosphor or scintillator layer or even as a filler, filling gaps—in part or integrally—appearing in form of voids or cracks between the preferred phosphor or scintillator needles in the coated layer. Moreover when laminating a polymer layer onto the deposited layer, it is not excluded that polymer material is filling, at least in part, the voids between those needles. If the voids are filled up to a reduced depth, i.e. less than 10%, and even more preferred up to less than 5%, cross-talk between needles is avoided. Furtheron it is not excluded to provide the phosphor or scintillator sheets or panels, before or after cutting in desired formats, with a moisture-resistant layer, in order to protect the moisture-sensitive phosphor or scintillator layer against deterioration. Particularly preferred layers are e.g. parylene (p-xylylene) layers as described in U.S. Pat. No. 6,710,356, whether or not overcoated with a transparent organic layer of silazane or siloxazane type polymeric compounds or mixtures thereof as described in US-Application 2004/0164251. In the method of applying a protecting parylene layer to phosphor or scintillator coatings as a “parylene layer” a halogen-containing layer was preferred. More preferably said “parylene layer” is selected from the group consisting of a parylene D, a parylene C and a parylene HT layer. In the particular case a cross-linked polymeric layer is advantageously formed on a phosphor or scintillator screen material, wherein the said polymeric material layer has been formed by reaction of at least one component, thereby forming self-condensing polymers. Reactive monomers are provided in form of heated vapor in order to form the desired condensation polymer on the substrate, wherein said condensation polymer is in form of a p-xylylene or “parylene” layer on the phosphor or scintillator screen substrate. Examples of these “parylene” layers are poly-p-xylylene (Parylene-N), poly-monochloro-p-xylylene (Parylene-C) and polydichloro-p-xylylene (Parylene-D). If desired a pigment can be integrated into a thin film of a poly-p-xylylene as has been described in JP-A 62-135520.

Apart from a photostimulable phosphor or scintillator layer, a prompt emitting luminescent phosphor may be coated in the vapor depositing apparatus used in the method according to the present invention. Such a luminescent phosphor is suitable for use e.g. in intensifying screens as used in screen/film radiography.

With respect to the specific applications, related with CR and DR, it is clear that in view of image quality, and more particularly in view of sharpness, binderless phosphor or scintillator layers as described hereinbefore are preferred. With respect thereto it is clear that vaporization of raw materials in the vapor depositing apparatus used for performing the method according to the present invention, in order to build the desired scintillator or phosphor layers is a preferred technique, provided that, according to the method of the present invention the layers have been deposited on a flexible substrate, wherein it is envisaged to deform the flexible support in order to get a flat sheet or panel, ready-for-use, suited for specific CR and DR applications. Other hygroscopic phosphor or scintillator layers besides the preferred CsBr:Eu phosphor that are advantageously prepared according to the method of the present invention are e.g. BaFCl:Eu, BaFBr:Eu and GdOBr:Tm, used in intensifying screens; CsI:Na applied in scintillator panels and storage phosphors suitable for use in computed radiography (CR) as e.g. BaFBr:Eu, BaFI:Eu, (Ba,Sr)F(Br,I):Eu, RbBr:T1, CsBr:Eu, CsCl:Eu and RbBr:Eu; or CsI:T1, Lu₂O₂S:xM and Lu₂O₅Si:xM, wherein M is selected from the group of rare earth elements consisting of Eu, Pr and Sm and wherein x is from 0.0001 to 0.2, which is particularly suitable for use in DR-cassettes as disclosed in US-Applications 2004/0262536 and 2005/0002490 respectively.

While the present invention will hereinafter be described in connection with preferred embodiments thereof, it will be understood that it is not intended to limit the invention to those embodiments.

### EXAMPLES

The crucible was in form of a boat having a length of 10 cm, a width of 35 mm and a height of 47.5 mm, composed of “tantalum” having a thickness of 0.25 mm, composed of 7 integrated parts, i.e. a crucible container (4), an internally heated chimney (2), a heat shield with slit (3) and a slot outlet (3′), an inner lid with small circular perforations (5) having a diameter of 2 mm, a ceramic ring as an isolator between crucible and chimney (6) and a “saving” or “reduction” part in order to fit crucible (4) to chimney (2).

The longitudinal parts were folded from one continuous tantalum base plate in order to overcome leakage and the head parts are welded. The chimney was provided with one linear infrared heater (quartz lamp) with a diameter of 10 mm (1) in order to heat the chimney in order to overcome condensation of vaporized materials. Moreover the chimney heater (1) was positioned in such a way that no direct heating of the substrate occurred, thanks to the position and the presence of a heat shield with slit (3) and slot outlet (3′). A lip opening of 12 mm as controllable outlet (3′) was used on top of the slit opening in the heat shielding member. The heat shield with slit opening thus provoked shielding heat in order to avoid escape of heat and loss of energy, required to provoke vapor escape and deposit onto the substrate support in a controlled and uniform way. The inner lid (5) with small perforations avoided spatter of molten and/or vaporized raw material onto the support or substrate in an uncontrolled and unlimited way.

As an isolation means a ceramic ring was used, and a perfect fitting between dimensions of the crucible and the chimney were further realized by means of the reduction part, between crucible, isolating ceramic ring and chimney.

CsBr was added to the crucible in an amount of 200 g and as a Eu-dopant precursor 0.5 wt % of EuOBr was added thereto, in order to vapor deposit the vaporized raw materials and to prepare a CsBr:Eu storage phosphor screen or panel.

Under vacuum pressure (a reduced pressure of 2×10 Pa equivalent with 2×10 mbar) maintained by a continuous inlet of argon gas into the vacuum chamber, and at a sufficiently high temperature of the vapor source (760° C.) and the chimney, the vapor thus obtained was escaping through the slot outlet of the vapor deposition apparatus to the support and was deposited thereupon while said support was rotating over the vapor stream. Said temperature of the vapor source was measured by means of thermocouples present outside and pressed under the bottom of the said crucible and by means of tantalum protected thermocouples present in the crucible and in the chimney.

In the Table 1 dimensions of the vapor cloud, as measured after different thickness depositions of the phosphor onto the panel support are summarized, i.e., while exhausting the raw materials present in the crucible, when said vapor cloud was escaping from a crucible unit, consisting of a crucible with a chimney according to the invention, having as a slit aperture in the heat shield (3) a length of 60 mm and a width of 11 mm.

TABLE 1
Inventive vaporizations and depositions

| Phosphor layer | Length of the | Width of | Ratio |
|---|---|---|---|
| thickness (μm) | cloud (mm) | the cloud (mm) | length/width |
| 1000 | 4 | 1 | 4.0 |
| 800 | 12 | 7 | 1.7 |
| 600 | 19 | 12 | 1.6 |
| 400 | 27 | 17 | 1.6 |
| 200 | 39 | 25 | 1.6 |

In the Table 2 dimensions of the vapor cloud, as measured after different thickness depositions of the phosphor onto the panel support are summarized, i.e., while exhausting the raw materials present in the crucible again, when said vapor cloud was escaping from a crucible without chimney, thus representing a comparative vapor deposition apparatus, differing from the present invention, while having a cover onto the crucible without a chimney, consisting of 24 holes having a diameter of 6 mm each, said holes being divided over a cover surface of 125 mm×50 mm.

TABLE 2
Comparative vaporizations and depositions

| Phosphor layer | Length of the | Width of | Ratio |
|---|---|---|---|
| thickness (μm) | cloud (mm) | the cloud (mm) | length/width |
| 1600 | 7 | 6 | 1.2 |
| 1400 | 11 | 10 | 1.1 |
| 1200 | 15 | 14 | 1.1 |
| 1000 | 18 | 16 | 1.1 |
| 800 | 22 | 20 | 1.1 |
| 600 | 27 | 25 | 1.1 |
| 400 | 33 | 30 | 1.1 |
| 200 | 44 | 39 | 1.1 |

As becomes clear from the results in the (inventive) Table 1, the ratio between length and width (perpendicular versus the length direction) of the vapor cloud, for whatever a degree of exhaustion of the raw materials in the crucible while vaporizing the said raw materials is higher than 1.3 for the inventive vaporization unit, being illustrative for the appearance of an “asymmetric” vapor deposition cloud.

Opposite thereto the results in the (comparative) Table 2 clearly show that the ratio between length and width (perpendicular versus the length direction) of the vapor cloud, for every degree of exhaustion of the raw materials in the crucible while vaporizing the said raw materials is lower than 1.3 when applying a comparative vaporization from a crucible with perforated cover. This is illustrative for the appearance of a more “symmetric” vapor deposition cloud while performing such a comparative vapor deposition method.

In Table 3 the properties of the configurations of the vaporization units as applied in the manufacturing of “comparative” needle image plates (NIPs CB24204 & 25502) and “inventive” needle image plates (NIPs CB25406 & 255504) are summarized, from a point of view of presence (or not) of a chimney, symmetry (or not) of the chimney with respect to position of the heating element, position of the outlet opening in the chimney (when present), position of the lamp as heating element in the chimney and coating weight as obtained onto the panel substrate when fully exhausting the crucible.

TABLE 3

| | | | | Position | | |
|---|---|---|---|---|---|---|
| | | Presence | Symmetry | of the | | |
| | | of a | of the | outlet | Position of the | Coating weight |
| NIP | | chimney | chimney | opening | lamp | (mg/cm²) |
| CB24204 | Comp. | NO | — | — | — | 63.3 |
| CB25502 | Comp. | YES | symmetric | middle | middle | 108.6 |
| CB25406 | Inv. | YES | asymmetric | middle | edge | 147.9 |
| CB25504 | Inv. | YES | asymmetric | edge | edge | 131.2 |

The results obtained for the coating weight, as represented in Table 3, clearly illustrate a higher yield—lower loss of material—as obtained for the inventive NIPs. A “symmetric” position of the lamp and of the outlet opening, even when a chimney is present, does not offer a sufficient yield if compared with the inventive NIPs, formed from an “asymmetric” vapor cloud as directed by an “asymmetric” position of the outlet opening and the inner heating lamp, resulting in an “asymmetric” chimney.

As an important result thus attained by applying the method according to the present invention, the yield, i.e. amount of deposited phosphor material in the inventive example exceeds the amount of deposited phosphor material with at least 25% when vaporization is applied in a comparative apparatus provided with a chimney and the said yield even exceeds the amount of deposited phosphor material with at least 100% when vaporization is applied in a comparative apparatus without chimney as becomes apparent from the data given in the summarizing Table 3.

Having described in detail preferred embodiments of the current invention, it will now be apparent to those skilled in the art that numerous modifications can be made therein without departing from the scope of the invention as defined in the appending claims.

### Parts List

(1) chimney heater element,
(2) internally heated chimney,
(3) heat shield with a slit (or an array of slits in one dimension) and a slot outlet (3′),
(4) crucible, tray or boat,
(5) inner lid with perforations,
(6) isolation means between crucible and chimney,
(7) a “saving” or “reduction” part in order to fit crucible (4) to chimney (2).

What is claimed is:

1. Method of preparing a storage phosphor or a scintillator layer on a support by vapor depositing from a crucible unit in a vapor deposition apparatus, while heating as phosphor or scintillator precursor raw materials a matrix component and an activator component or a precursor component thereof, said crucible unit comprising a bottom and surrounding side walls as a container for the said phosphor or scintillator precursor raw materials present in said crucible, said crucible being provided with an internal lid with perforations (5) and said crucible unit further comprising a chimney as part of the said crucible unit and a slit allowing molten, liquefied phosphor or scintillator precursor raw materials to escape in vaporized form under reduced pressure from said crucible unit in order to become deposited as a phosphor or scintillator layer onto said support; wherein at least one heating means (1) in the chimney (2) is positioned under a heat shield with a slit (3) and a slot outlet (3′), covering thereby said crucible unit and making part of said chimney (2), so that said heating means (1) cannot be observed when looking into the vaporization unit through said slot outlet (3′) from any point in the plane of the said support present as a vapor deposition target in the said vapor deposition apparatus and wherein, while vaporizing said phosphor or scintillator precursor raw materials, a vapor cloud escapes from said slot outlet (3′) in the direction of the said support so that the ratio of the longest radius of the said vapor cloud versus the radius perpendicular thereto, when projected onto the phosphor or scintillator plate or panel from whatever an intersection through the said vapor cloud between slot outlet (3′) and support is at least 1.3, said intersection being taken parallel with the said support.

2. Method according to claim 1, wherein an isolation means (6) between said chimney (2) and said crucible (4) is present.

3. Method according to claim 2, wherein said isolation means (6) is in form of an isolating ring or layer.

4. Method according to claim 3, wherein said isolating ring or layer comprises as an isolating material an oxide selected from the group consisting of Al₂O₃, SiO₂, quartz, glass, ceramics and a combination thereof.

5. Method according to claim 1, wherein the step of heating said precursor raw materials in the crucible in liquid form proceeds up to a temperature T1 and wherein the step of heating said precursor raw materials in vaporized form in said chimney (2) proceeds by means of said at least one heating means (1) in the chimney (2) up to a temperature T2, wherein a positive difference in temperature [T2−T1] is maintained.

6. Method according to claim 5, wherein said temperatures T1 and T2 are attained by radiation heating, inductive heating, resistive heating or a combination thereof.

7. Method according to claim 1, wherein a “saving” or “reduction” part (7), is provided between crucible (4) and chimney (2) in order to make the said crucible (4) and the said chimney (2) fit to each other.

8. Method according to claim 1, wherein CsX is a matrix component and EuX₂, EuX₃, EuOX or a mixture thereof are activator components, X representing Cl, Br, I or a combination thereof.

9. Method according to claim 1, wherein CsₓEu_{y}X′_{(x+αy)} is an activator precursor material, wherein x, y and α are integers, wherein x/y is more than 0.25 and wherein a is at least 2 and wherein X′ represents F, Cl, Br, I or a combination thereof.

10. Method according to claim 1, wherein said storage phosphor is CsBr:Eu.

11. Method according to claim 1, wherein CsX′ is a matrix component and T1X′ or T1X′₃ or a mixture thereof are activator components, X′ representing F, Cl, Br, I or a combination thereof.

12. Method according to claim 1, wherein said scintillator is CsI:T1.

13. Method according to claim 1, wherein said support is composed of glass, a ceramic material, a polymeric material, a metal or a combination thereof.

14. Method according to claim 1, wherein said vapor deposition proceeds in a batch process.

15. Method according to claim 1, wherein said vapor deposition proceeds in a continuous process.

16. Vapor deposition apparatus comprising a crucible unit consisting of a crucible (4) and a chimney (2), wherein said crucible is provided with an internal lid with perforations (5)and wherein said chimney (2) is covered with a heat shield with a slit (3) and a slot outlet (3′), wherein said chimney (2) comprises at least one chimney heater element (1) positioned asymmetrically versus an axis perpendicular to the centre of the said internal lid with perforations (5), in that said chimney heater element(s) is (are) not observed from any point outside said slot outlet (3′).

17. Vapor deposition apparatus according to claim 16, wherein isolation means (6) are present between said crucible (4) and said chimney (2).

18. Vapor deposition apparatus according to claim 16, wherein a “saving” or “reduction” part (7) is present as a fitting means between said crucible (4) and said chimney (2).

19. Vapor deposition apparatus according to claim 17, wherein a “saving” or “reduction” part (7) is present as a fitting means between said crucible (4) and said chimney (2).

20. Vapor deposition apparatus according to claim 19, wherein not any axis perpendicular to the said inner lid (5) of crucible (4) and not any axis parallel to the said axis and passing through the “saving” or “reduction” part (7) together pass through the said slot outlet (3′).
